(19) United States
(12) Patent Application Publication
(10) Pub. No.: US 2014/0251577 A1
(43) Pub. Date: Sep. 11, 2014

(54) COOLING FRAME WITH INTEGRATED HEAT PIPES

(71) Applicant: THERMAL CORP., Wilmington, DE (US)

(72) Inventor: Matthew J. Connors, Lancaster, PA (US)

(73) Assignee: THERMAL CORP., Wilmington, DE (US)

(21) Appl. No.: 13/789,751

(22) Filed: Mar. 8, 2013

(51) Int. Cl. H05K 7/20

(52) U.S. Cl. CPC H05K 7/20
USPC 165/67

(57) ABSTRACT

A heat-transfer system is provided for conveying heat from a heat source, the heat-transfer system generally including a frame for coupling to the heat source, wherein the frame is insertable into a first slot of a cooling chassis, and a heat-transfer rail extending parallel to the frame at an offset distance, wherein the offset distance is dimensioned such that the heat-transfer rail is insertable into a second slot of the cooling chassis. At least one heat-transfer device couples the heat-transfer rail to the frame.

### BACKGROUND

A heat pipe can conduct heat from a heat source such as from an electronic device through vapor heat transfer. Typically, the heat pipe includes a working fluid, an evaporator portion, and a condenser portion. The working fluid is vaporized at the evaporator portion. The vapor is received at the condenser portion, whereupon the vapor is condensed to form a liquid working fluid. The condensed working fluid is returned to the evaporator portion, thereby completing a cycle.

A heat pipe can be used to dissipate heat generated by a computer component such as a printed circuit board (“PCB”). PCBs are often mounted within a chassis. The heat pipe may transfer the heat to a metal wall of the chassis. The heat may then be sent to an external heat sink, and finally taken away by either cool air circulating about the heat sink or a cold plate.

### SUMMARY

In some embodiments, a heat-transfer system is provided for conveying heat from a heat source, the heat-transfer system generally including a frame for coupling to the heat source, wherein the frame is insertable into a first slot of a cooling chassis, and a heat-transfer rail extending parallel to the frame at an offset distance, wherein the offset distance is dimensioned such that the heat-transfer rail is insertable into a second slot of the cooling chassis. At least one heat-transfer device couples the heat-transfer rail to the frame.

Also, in some embodiments, a circuit card module is provided for conveying heat from a heat source, the circuit card module generally including a frame for coupling to the heat source, wherein the frame is insertable into a first slot of a cooling chassis, and at least one heat-transfer device including a first portion for coupling to the frame and a second portion spaced from the first portion at an offset distance. The offset distance is dimensioned such that the second portion is insertable into a second slot of the cooling chassis.

In some embodiments, a circuit card module is provided for conveying heat from a heat source, the circuit card module generally including a frame for coupling to the heat source, wherein the frame is insertable into a first slot of a cooling chassis, a heat-transfer rail extending parallel to the frame at an offset distance, wherein the offset distance is dimensioned such that the heat-transfer rail is insertable into a second slot of the cooling chassis, and at least one heat pipe including an evaporator portion, a condenser portion in fluid communication with the evaporator portion, and a working fluid flowing between the evaporator portion and the condenser portion. The evaporator portion is coupled to the frame and the condenser is coupled to the heat-transfer rail.

Other aspects of the invention will become apparent by consideration of the detailed description and accompanying drawings.

### BRIEF DESCRIPTION OF THE DRAWINGS

FIG. 1 is a perspective view of a circuit card module, illustrating a cooling chassis and a heat-transfer system insertable thereto.

FIG. 2 is a perspective view of the heat-transfer system of FIG. 1, illustrating a frame, a pair of heat-transfer rails, and a plurality of heat-transfer devices.

FIG. 3 is a perspective view similar to FIG. 2, illustrating the frame and heat-transfer rails, with the heat-transfer devices removed.

FIG. 4 is an end view of the heat-transfer system of FIG. 2.

FIG. 5 is a cross-sectional view taken along line V-V of FIG. 2.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limited. The use of “including,” “comprising” or “having” and variations thereof herein is meant to encompass the items listed thereafter and equivalents thereof as well as additional items. The terms “mounted,” “connected” and “coupled” are used broadly and encompass both direct and indirect mounting, connecting and coupling. Further, “connected” and “coupled” are not restricted to physical or mechanical connections or couplings, and can include electrical connections or couplings, whether direct or indirect.

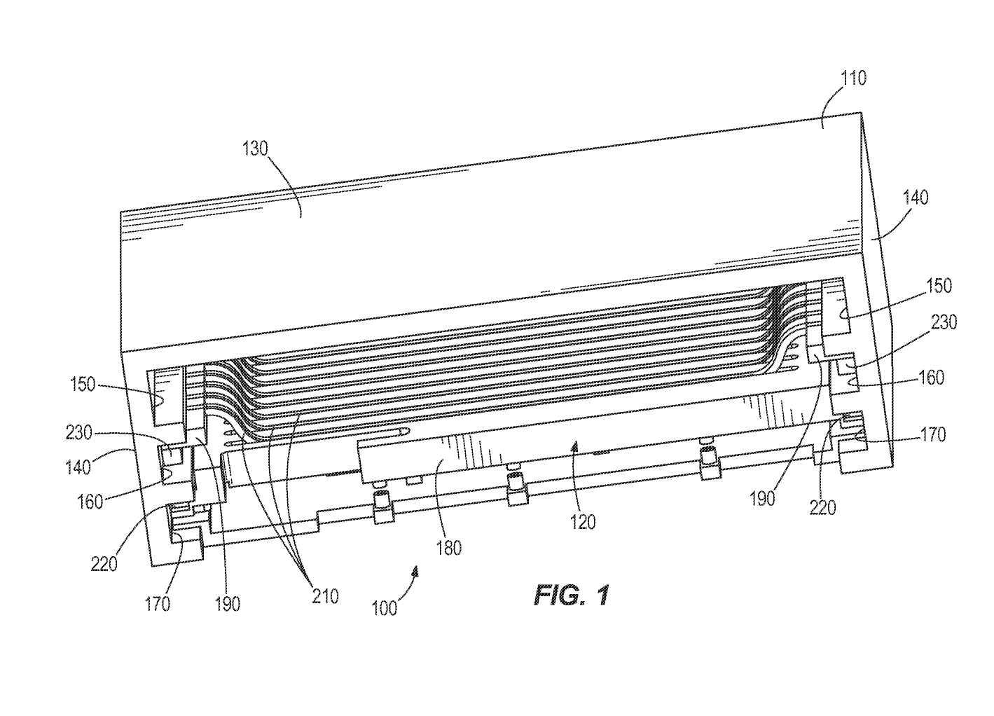

FIG. 1 is a perspective view of a circuit card module 100 for conveying heat from a heat source (not shown) such as used in military avionics meeting VME/VPX standards. For example, the heat source can include, but is not limited to, processor chips, I/O modules, voltage regulators, power chips, etc. that are mounted to a printed circuit board. The circuit card module 100 includes a cooling chassis 110 and a heat-transfer system 120 insertable into the cooling chassis 110. In the illustrated embodiment, the cooling chassis 110 includes a top wall or cover surface 130 and a pair of walls 140 that are each extending from the cover surface 130 at a substantially right angle. As used herein, the terms “top,” “bottom,” “front,” “rear,” “side,” and other directional terms are not intended to require any particular orientation, but are instead used for purposes of description only. In some embodiments, the cooling chassis 110 can be provided with fewer or more than two walls 140. In the illustrated embodiment, each wall 140 includes three slots 150, 160, 170 extending substantially parallel to one another at a respective distance relative to the cover surface 130. In other embodiments, the walls 140 can include at least two slots extending substantially parallel to one another at a respective distance relative to the cover surface 130.

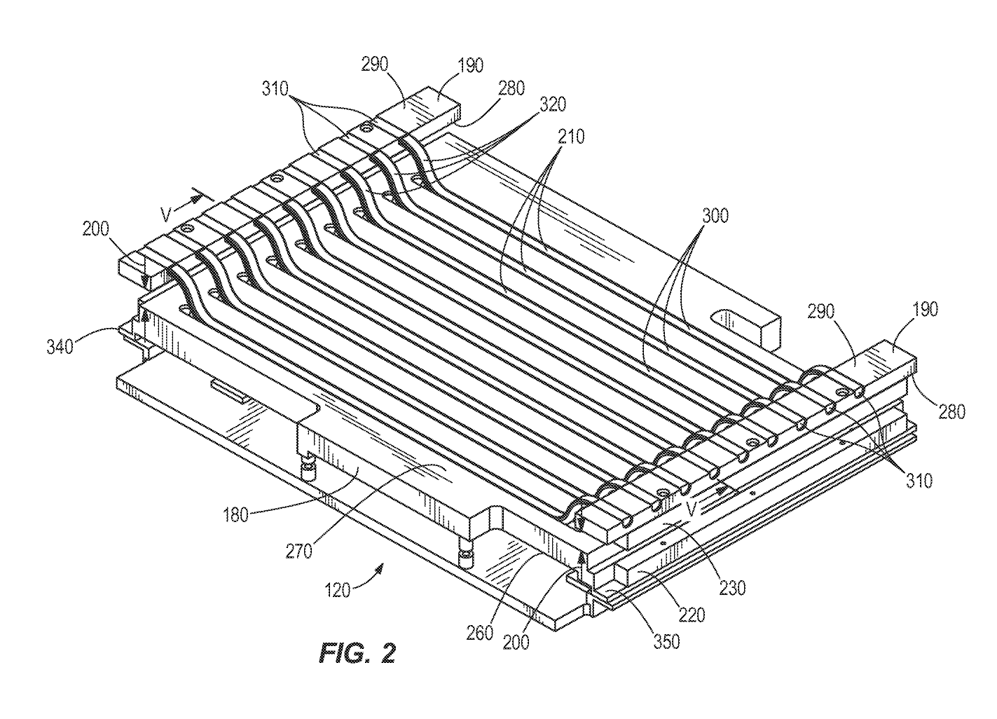

Referring also to FIG. 2, the heat-transfer system 120 includes a frame 180 for coupling to the heat source, heat-transfer rails 190 extending parallel to the frame 180 at an offset distance 200, and heat-transfer devices 210 coupling the heat-transfer rails 190 to the frame 180. In the illustrated embodiment, the frame 180 is insertable into the slot 170 of the cooling chassis 110. The offset distance 200 is such that the heat-transfer rails 190 are insertable into an adjacent slot 160 of the cooling chassis 110. The heat-transfer rails 190 facilitate heat removal by four slots (two slots on each wall 140) of the cooling chassis 110. In some embodiments, the frame 180 and heat-transfer rails 190 may be constructed from aluminum. In other embodiments, one or both of the frame 180 and heat-transfer rails 190 may be made from other materials. Although FIGS. 1 and 2 illustrate the heat-transfer system 120 as including a pair of heat-transfer rails 190, in other embodiments the heat-transfer system 120 may include one or more heat-transfer rails 190.

In the illustrated embodiment, both the frame 180 and the heat-transfer rails 190 are secured to the cooling chassis 110 using a respective wedge lock 220, 230. In some embodiments, the wedge locks 220, 230 can comprise the “card-lok” clamp manufactured by Calmark Corp of San Gabriel Calif., and disclosed in U.S. Pat. Nos. 5,224,016 and 4,819,713, which patents are hereby incorporated herein by reference. For example, the wedge locks 220, 230 may include a plurality of trapezoidal-shaped wedge members that are arranged in an end-to-end fashion with successive wedge members being oppositely oriented. The wedge locks 220, 230 can adjustably expand and can also conduct heat to the cooling chassis 110.

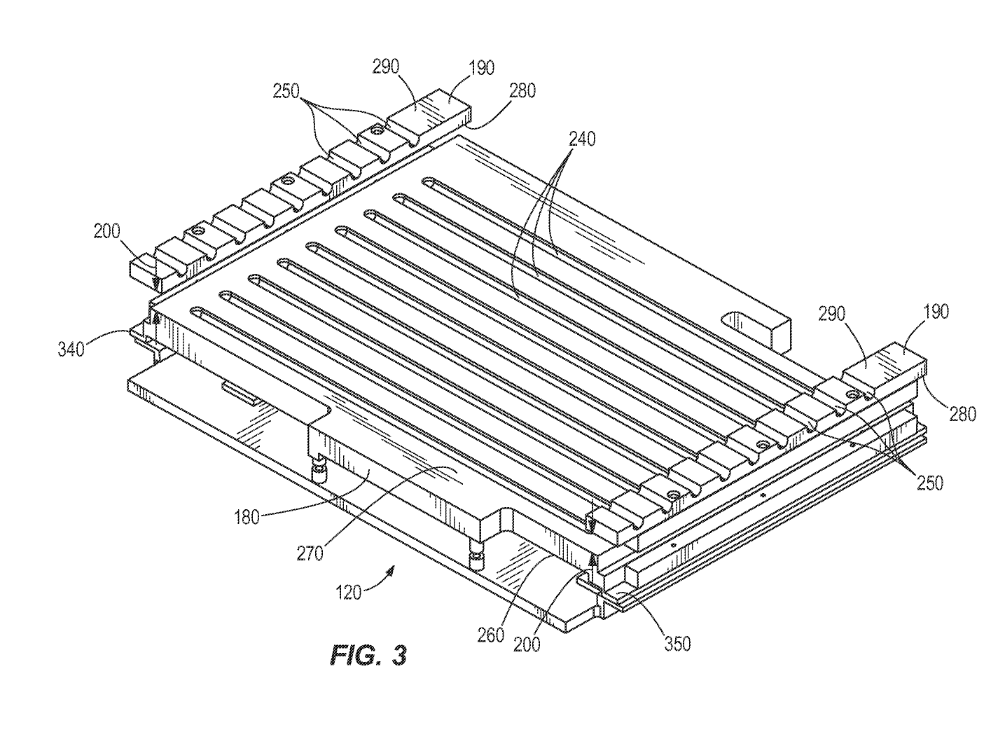

Referring also to FIG. 3, the frame 180 and heat-transfer rails 190 each include recessed portions 240, 250 for receiving the heat-transfer devices 210. In the illustrated embodiment, the frame 180 defines a first face 260 proximate the heat source and a second face 270 opposite the first face 270. The recessed portions 240 are formed in the second face 270. Likewise, each heat-transfer rail 190 defines a first face 280 proximate the heat source and a second face 290 opposite the first face 280, and the recessed portions 250 are formed in the second face 290. In the illustrated embodiment, the recessed portions 240, 250 extend substantially in line with each other. In other embodiments, however, the recessed portions 240, 250 may extend without necessarily being in line with one another. In still other embodiments, one or both of the frame 180 and heat-transfer rails 190 can include ribs or raised portions (not shown) for holding the heat-transfer devices 210 in place.

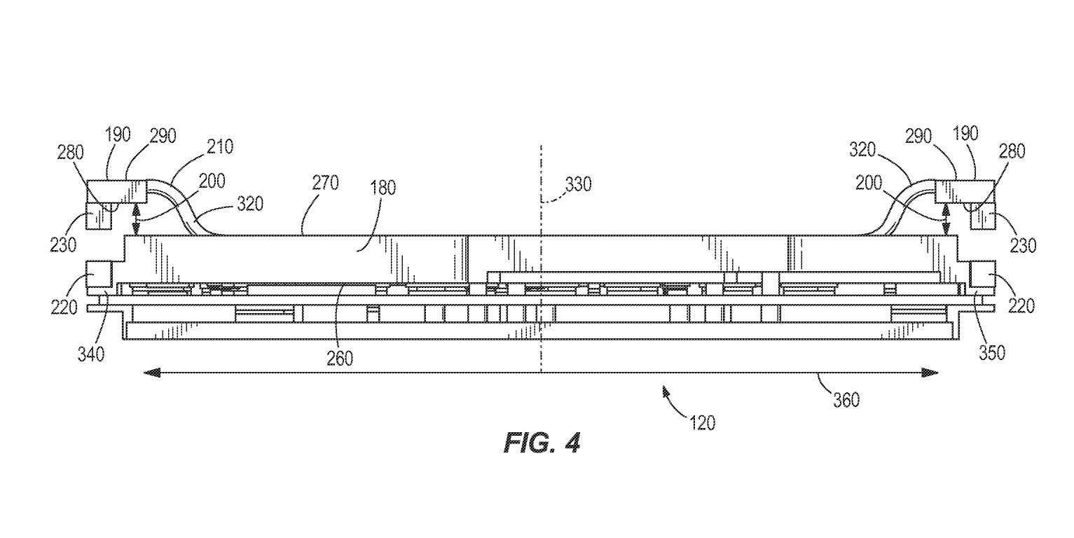

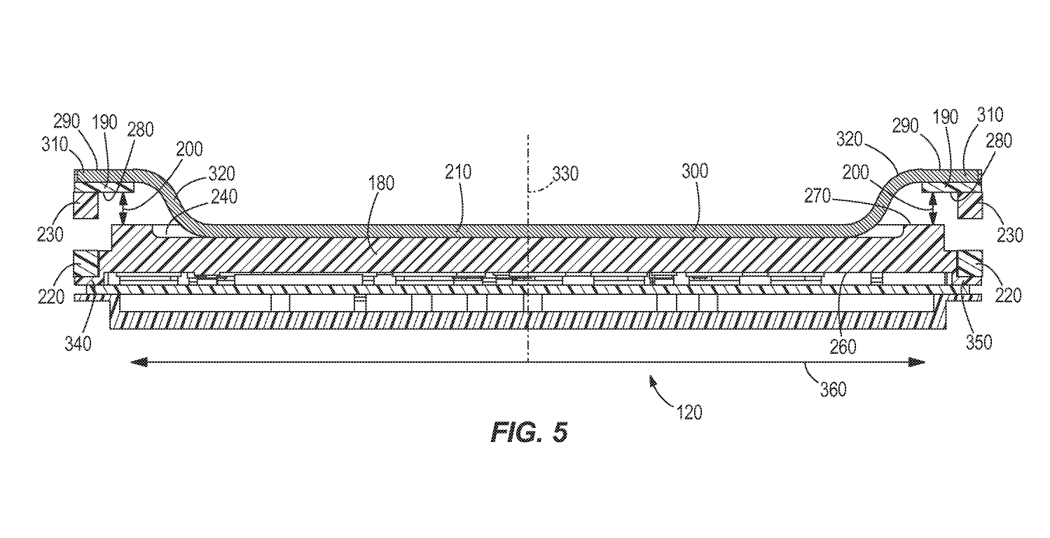

Referring also to FIGS. 4 and 5, the illustrated heat-transfer device 210 is a heat pipe or thermosyphon, although other structures performing the same or substantially similar function as the heat pipe or thermosyphon 210 disclosed herein can be used instead. In general, the illustrated heat-transfer device 210 includes an evaporator portion 300 having a length for generating a vapor, a pair of condenser portions 310 in fluid communication with the evaporator portion 300, and a working fluid (not shown) flowing between the evaporator portion 300 and the condenser portions 310. The evaporator portion 300 is coupled to the frame 180 and the condenser portions 310 are coupled to the heat-transfer rails 190. In the illustrated embodiment, the evaporator portion 300 is received or embedded in the recessed portion 240 of the frame 180 so that an outer surface of the heat-transfer device 210 is substantially flush with the frame 180. The assembly of the evaporator portion 280 and the frame 180 can thereby give a smooth substantially linear appearance. In other embodiments, however, the evaporator portion 300 can be slightly recessed relative to the outer surface of the frame 180, or even slightly raised relative to the outer surface of the frame 180.

In the illustrated embodiment, the heat source is positioned to be in contact with an underside of the frame 180, and thereby makes an indirect thermal contact with the evaporator portion 300. The working fluid is vaporized at the evaporator portion 300. The vapor flows from the evaporator portion 300 and is received at the condenser portions 310, whereupon the vapor is condensed to form a liquid working fluid. Capillary action or gravity returns the condensed working fluid to the evaporator portion 300, thereby completing a cycle. In the illustrated heat pipe 210, the evaporator portion 300 and the condenser portions 310 are both enclosed by a common wall, which may be constructed from any suitable material, such as a metallic (e.g., aluminum, copper, magnesium, or stainless steel) material or alloy thereof.

Any number of fluids can be suitable as a working fluid so long as they have a liquid phase and a vapor phase. Suitable working fluids include, but are not limited to, water, ammonia, Freon, acetone, ethane, ethanol, heptane, methanol, potassium, sodium, hydrocarbons, fluorocarbons, methyl chloride, liquid metals such as cesium, lead, lithium, mercury, rubidium, and silver, cryogenic fluids such as helium and nitrogen, and other fabricated working fluids. The particular working fluid can be chosen depending on the operating temperature requirements, the material of the heat-transfer device 210 wall, or upon preferences for the particular heat-transfer device 210.

An intermediate arc portion 320 extends between the evaporator portion 300 and the condenser portions 310. Although FIGS. 4 and 5 illustrate the intermediate arc portion 320 as forming an S shape, in other embodiments the intermediate arc portion 320 may assume any geometric form, including, but not limited to, a polyhedral or curved shape. In the illustrated embodiment, each heat-transfer device 210 is substantially symmetrical when viewed from above along a centerline axis 330 extending substantially perpendicular to the frame 180. In other embodiments, however, the heat-transfer devices 210 are not necessarily symmetrical when viewed along the centerline axis 330. The illustrated evaporator and condenser portions 300, 310 extend respectively along a substantially linear length. In some embodiments, the heat-transfer device 210 flexes at the intermediate arc portion 320 so as to afford a displacement of one or both of the evaporator and condenser portions 300, 310, e.g., in a direction parallel to the centerline axis 330. The flexibility of the heat-transfer device 210 can permit a degree of flexibility in the locations of the heat-transfer rails 190, which may be needed if the distances between adjacent slots in the cooling chassis 110 are not uniform.

The frame 180 defines a pair of side portions 340, 350 insertable into the slot 170. A substantially linear direction 360 extends between the side portions 340, 350. In the illustrated embodiment, the heat-transfer devices 210 are configured so as to facilitate transferring heat along the substantially linear direction 360. In other embodiments, however, the heat-transfer devices 210 may be configured so as to facilitate transferring heat along other directions, including directions that may not necessarily be linear. Although FIG. 2 illustrates the heat-transfer devices 210 as extending substantially parallel to one another, the heat-transfer devices 210 may be extending non-parallel (e.g., angled) to one another.

In some embodiments, the heat-transfer system 120 further comprises a substantially linear heat-transfer device (not shown) that does not necessarily include the intermediate arc portion 320, and that extends from the frame 180 at a substantially same height thereof. The substantially linear heat-transfer device may be used to direct heat to alternate locations on the cooling chassis 110. For example, a first heat-transfer device 210 may direct heat to the slot 160, and the next heat-transfer device may be substantially straight to direct heat horizontally. In some embodiments, every other heat-transfer device can be substantially straight to direct the heat to alternate locations on the cooling chassis 110. In other embodiments, every second, third, or fourth heat-transfer device can be substantially straight depending on the cooling requirements or upon preferences for the particular heat-transfer device 210.

Although the invention has been described in detail with reference to certain preferred embodiments, variations and modifications exist within the scope and spirit of one or more independent aspects of the invention as described.

1. A heat-transfer system for conveying heat from a heat source, the heat-transfer system comprising:
a frame for coupling to the heat source, wherein the frame is insertable into a cooling chassis;
a heat-transfer rail extending parallel to the frame at an offset distance from the frame; and
at least one flexible heat-transfer device coupling the heat-transfer rail to the frame, wherein the heat-transfer device includes a first portion coupled to the frame and a second portion coupled to the heat transfer rail, the second portion being insertable into a slot of the cooling chassis.

2. The heat-transfer system of claim 1, wherein the heat-transfer device includes two portions for coupling to the frame and the heat-transfer rail, respectively, and an intermediate arc portion extending between the two portions.

3. The heat-transfer system of claim 2, wherein the two portions extend respectively along a substantially linear length, and wherein the heat-transfer device flexes at the intermediate arc portion so as to afford a displacement of at least one of the two portions.

4. The heat-transfer system of claim 2, wherein the slot is a first slot, and wherein the offset distance is dimensioned such that the frame is insertable into a second, separate slot of the cooling chassis.

5. The heat-transfer system of claim 1, wherein the frame and the heat-transfer rail each include a recessed portion for receiving the heat-transfer device.

6. The heat-transfer system of claim 5, wherein the frame and the heat-transfer rail respectively define a first face proximate the heat source and a second face opposite the first face, and wherein each recessed portion is formed in the respective second face.

7. The heat-transfer system of claim 5, wherein the recessed portions extend substantially in line with each other.

8. The heat-transfer system of claim 1, wherein the frame defines a pair of side portions and a substantially linear direction extending therebetween, and wherein the heat-transfer devices are configured so as to facilitate transferring heat along the substantially linear direction.

9. The heat-transfer system of claim 1, wherein the heat-transfer system comprises a first heat-transfer device and a second heat-transfer device, and wherein the first and second heat-transfer devices extend substantially parallel to each other.

10. The heat-transfer system of claim 1, wherein the heat-transfer device includes a heat pipe.

11. The heat-transfer system of claim 1, wherein the heat-transfer device includes an evaporator having a length for generating a vapor, a condenser in fluid communication with the evaporator, and a working fluid flowing between the evaporator and the condenser.

12. The heat-transfer system of claim 1, further comprising a heat-transfer device extending substantially coplanar with the frame.

13. A circuit card module for conveying heat from a heat source, the circuit card module comprising:
a frame for coupling to the heat source, wherein the frame is insertable into a cooling chassis; and
at least one flexible heat pipe including a first portion for coupling to the frame and a second portion spaced from the first portion at an offset distance from the first portion, the second portion insertable into a slot of the cooling chassis such that the second portion is in direct contact with the cooling chassis.

14. The circuit card module of claim 13, wherein the cooling chassis includes a cover surface and one or more walls extending therefrom, at least one of the walls including two slots extending substantially parallel to one another at a respective distance relative to the cover surface.

15. The circuit card module of claim 14, further comprising a heat-transfer rail, the heat transfer rail engaging the second portion of the heat pipe and being insertable into one of the two slots.

16. The circuit card module of claim 13, wherein the heat pipe includes an intermediate arc portion extending between the first and second portions.

17. The circuit card module of claim 16, wherein the heat pipe flexes at the intermediate arc portion so as to afford a displacement of at least one of the two portions.

18. The circuit card module of claim 16, wherein the intermediate arc portion forms an S shape.

19. The circuit card module of claim 13, wherein the frame includes a recessed portion for receiving the heat pipe.

20. The circuit card module of claim 19, wherein the frame defines a first face proximate the heat source and a second face opposite the first face, and wherein the recessed portion is formed in the second face.

21. The circuit card module of claim 13, wherein the frame defines a pair of side portions insertable into slots of the cooling chassis, and a substantially linear direction extending therebetween, and wherein the heat pipe is configured so as to facilitate transferring heat along the substantially linear direction.

22. The circuit card module of claim 13, wherein the circuit card module comprises a first flexible heat pipe and a second flexible heat pipe, and wherein the first and second heat pipes extend substantially parallel to each other.

23. A circuit card module for conveying heat from a heat source, the circuit card module comprising:
a frame for coupling to the heat source, wherein the frame is insertable into a first slot of a cooling chassis;
a heat-transfer rail extending parallel to the frame at an offset distance, wherein the offset distance is dimensioned such that the heat-transfer rail is insertable into a second slot of the cooling chassis; and
at least one heat pipe including an evaporator portion, a condenser portion in fluid communication with the evaporator portion, and a working fluid flowing between the evaporator portion and the condenser portion, wherein the evaporator portion is coupled to the frame and the condenser portion is coupled to the heat-transfer rail.

24. A heat-transfer system for conveying heat from a heat source, the heat-transfer system comprising:
a frame for coupling to the heat source, wherein the frame is insertable into a cooling chassis;
a heat transfer rail extending parallel to the frame at an offset distance from the frame; and
a heat transfer device having a first portion coupled to the frame and a second portion coupled to the heat transfer rail along an outer surface of the heat transfer rail, the outer surface facing opposite the heat source, and wherein both the heat transfer rail and the second portion are extendable into a slot in the cooling chassis.

25. A heat-transfer system for conveying heat from a heat source, the heat-transfer system comprising:
a frame for coupling to the heat source, wherein the frame is insertable into a cooling chassis;
a heat transfer rail extending parallel to the frame at an offset distance from the frame; and
a heat transfer device having a first portion coupled to the frame and a second portion coupled to the heat transfer rail along an outer surface of the heat transfer rail, the outer surface being located opposite a wedge lock located in a slot in the cooling chassis, and wherein both the heat transfer rail and the second portion are extendable into the slot relative to the wedge lock.
